(19) United States
(12) Patent Application Publication
(10) Pub. No.: US 2025/0107045 A1
(43) Pub. Date: Mar. 27, 2025

(54) SYSTEMS AND METHODS FOR COOLING ACCELERATORS HAVING BACK SIDE POWER DELIVERY COMPONENTS

(71) Applicant: Advanced Micro Devices, Inc., Santa Clara, CA (US)

(72) Inventors: Girish Anant Kini, Santa Clara, CA (US); Shardul Suresh Adkar, Austin, TX (US); Salvador D. Jimenez, III, Austin, TX (US); Mark Steinke, Austin, TX (US); Ethan Cruz, Austin, TX (US); Edgar Stone, Austin, TX (US); Ahmed Mohamed Abou-Alfotouh, Santa Clara, CA (US)

(73) Assignee: Advanced Micro Devices, Inc., Santa Clara, CA (US)

(21) Appl. No.: 18/471,888

(22) Filed: Sep. 21, 2023

(51) Int. Cl. H05K 7/20

(52) U.S. Cl. CPC H05K 7/2039

(57) ABSTRACT

A method for cooling accelerators having back side power delivery components can include providing a printed circuit board having a first side that includes an integrated circuit and a first set of one or more power delivery components and a second side that is opposite the first side and that includes a second set of one or more power delivery components. The method can also include positioning a first cooling system to cool the integrated circuit and the first set of one or more power delivery components. The method can further include positioning a second cooling system to cool the second set of one or more power delivery components. Various other methods and systems are also disclosed.

### BACKGROUND

An integrated circuit or monolithic integrated circuit (e.g., an IC, a chip, or a microchip) is a set of electronic circuits on one small flat piece (e.g., chip) of semiconductor material, usually silicon. Integrated circuits can be implemented in various forms, such as expansion cards (e.g., graphics accelerator cards).

In computing, an expansion card (e.g., an expansion board, adapter card, peripheral card, or accessory card) is a printed circuit board that can be inserted into an electrical connector, or expansion slot (e.g., bus slot) on a computer's motherboard (e.g., backplane) to add functionality to a computer system. Sometimes the design of the computer's case and motherboard involves placing most or all of these slots onto a separate, removable card.

Typically, such cards are referred to as riser cards in part because they project upward from the board and allow expansion cards to be placed above and parallel to the motherboard. Various standards define requirements for expansion cards, including power delivery requirements and form factors. One such standard corresponds to open compute project (OCP) accelerator module (OAM) for graphics accelerator cards.

A graphics card (e.g., video card, display card, graphics adapter, VGA card/VGA, video adapter, display adapter, or graphics processing unit (GPU)) is a computer expansion card that can generate a feed of graphics output to a display device such as a monitor. Graphics cards are sometimes called discrete or dedicated graphics cards to emphasize their distinction from an integrated graphics processor on the motherboard or the central processing unit (CPU). A GPU that performs the necessary computations is the main component in a graphics card.

Most graphics cards are not limited to simple display output. The GPU can be used for additional processing, which reduces the load from the CPU. Additionally, some computing platforms allow using graphics cards for general-purpose computing. Applications of general-purpose computing on graphics cards include artificial intelligence (Al) training, cryptocurrency mining, and molecular simulation. An Al accelerator is a class of specialized hardware accelerator or computer system designed to accelerate artificial intelligence and machine learning applications, including artificial neural networks and machine vision.

Usually, a graphics card comes in the form of a printed circuit board (e.g., expansion board) that can be inserted into an expansion slot. Others can have dedicated enclosures, and they can be connected to the computer via a docking station or a cable. These are known as external GPUs (eGPUs). Graphics cards are often preferred over integrated graphics for increased performance.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a flow diagram of an example method for cooling accelerators having back side power delivery components.

FIG. 2 is a block diagram illustrating an apparatus implementing systems and methods for cooling accelerators having back side power delivery components.

FIG. 3 is a block diagram illustrating an apparatus implementing systems and methods for cooling accelerators having back side power delivery components in which a first cooling system and a second cooling system are directly coupled to one another.

FIG. 4 is a block diagram illustrating an apparatus implementing systems and methods for cooling accelerators having back side power delivery components in which a printed circuit board has one or more cutouts therein configured to accommodate passage therethrough of a heat transfer path.

FIG. 5 is a block diagram illustrating an apparatus having a front side cooling system that includes an air-cooled heat sink.

FIG. 6 is a block diagram illustrating an apparatus having back side power delivery components.

FIG. 7 is a block diagram illustrating a back side cooling system having one or more fastener features.

FIG. 8 is a block diagram illustrating a front side cooling system that includes an air-cooled heat sink and one or more fastener features.

FIG. 9 is a block diagram illustrating front side and back side cooling systems directly coupled by a breakable heat transfer path that transfers thermal energy through a thermal interface material.

FIG. 10 is a block diagram illustrating implementation of fastener features to directly couple front and back side cooling systems directly coupled by a breakable heat transfer path that transfers thermal energy through a thermal interface material.

FIG. 11 is a block diagram illustrating a printed circuit board having one or more cutouts therein configured to accommodate passage therethrough of a heat transfer path.

FIG. 12 is a block diagram illustrating an apparatus implementing systems and methods for cooling accelerators having back side power delivery components in which a front side cooling system and a back side cooling system are directly coupled to one another, and the front side cooling system includes an air-cooled heat sink.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for cooling accelerators having back side power delivery components. For example, by positioning a first cooling system (e.g., including an air cooled heat sink) to cool an integrated circuit and a first set of one or more power delivery components on a front side of a printed circuit board, and by positioning a second cooling system (e.g., including a cooling element (e.g., copper plate, heat pipes, vapor chambers, three-dimensional vapor chambers, or combinations thereof)) to cool a second set of one or more power delivery components on a back side of the printed circuit board, the disclosed systems and methods can cool an accelerator having back side power delivery components. In some implementations, the disclosed systems and methods can include direct coupling of the first cooling system and the second cooling system to one another. In some of these implementations, the second cooling system can include a heat transfer path (e.g., copper pillars, copper blocks, heat pipes, vapor chambers, three-dimensional vapor chambers, or combinations thereof) between the first cooling system and the second cooling system. In some of these implementations, the heat transfer path can be a breakable heat transfer path that can be configured to transfer the thermal energy through a thermal interface material. Alternatively or additionally, some of these implementations can include a printed circuit board having one or more cutouts therein configured to accommodate passage therethrough of the heat transfer path.

The disclosed systems and methods can yield numerous benefits. For example, some implementations of the disclosed systems and methods can enable higher power (e.g., greater than 800 Watts) and performance with air-cooling. Additionally, some implementations of the disclosed systems and methods can avoid a need for any new data center infrastructure with air flow rates being similar to existing platform boundary conditions. Also, some implementations of the disclosed systems and methods can incorporate the back side cooling system within a bottom stiffener, thus improving structural rigidity. Further, some implementations of the disclosed systems and methods can realize easy assembly and disassembly by using a breakable heat transfer path while using current standard operating procedures (e.g., avoiding a requirement for complex tools). Further, some implementations of the disclosed systems and methods can exhibit reduced printed circuit board (PCB) copper planes and numbers of layers, thus achieving a reduced PCB cost. Further, some implementations of the disclosed systems and methods can experience reduced power path resistance between a voltage regulator and a processor, thus achieving reduced PCB copper losses, increased conversion efficiency, increased useful throughput power, and reduced power delivery network (PDN) impedance from a voltage regulator to a processor for reduced PDN noise. Finally, some implementations of the disclosed systems and methods can provide a low profile cooling system that allows a combination of the cooling system and the backside PDCs to fit within open compute project (OCP) accelerator module (OAM) form factors (e.g., eight millimeters of clearance on the back side of the PCB).

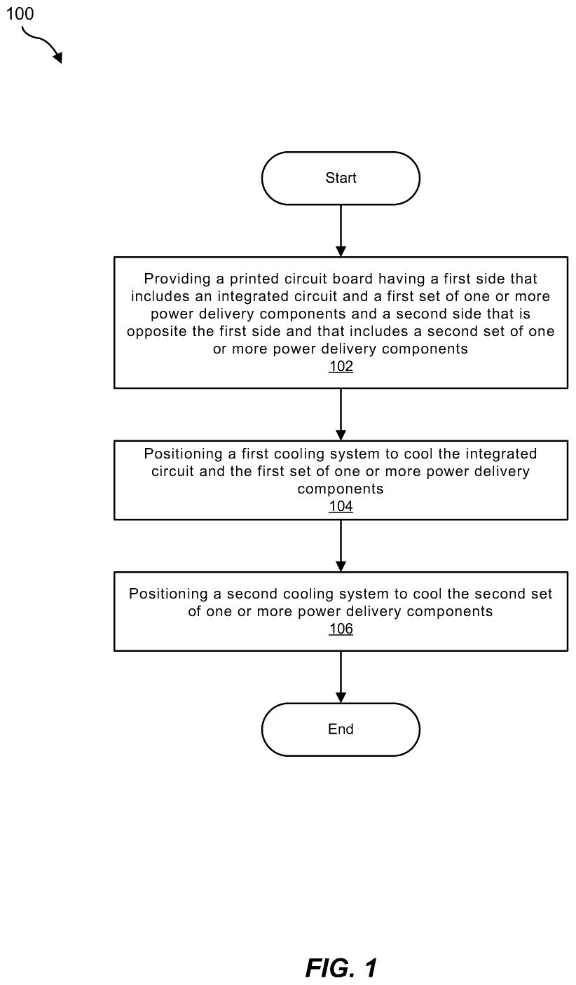

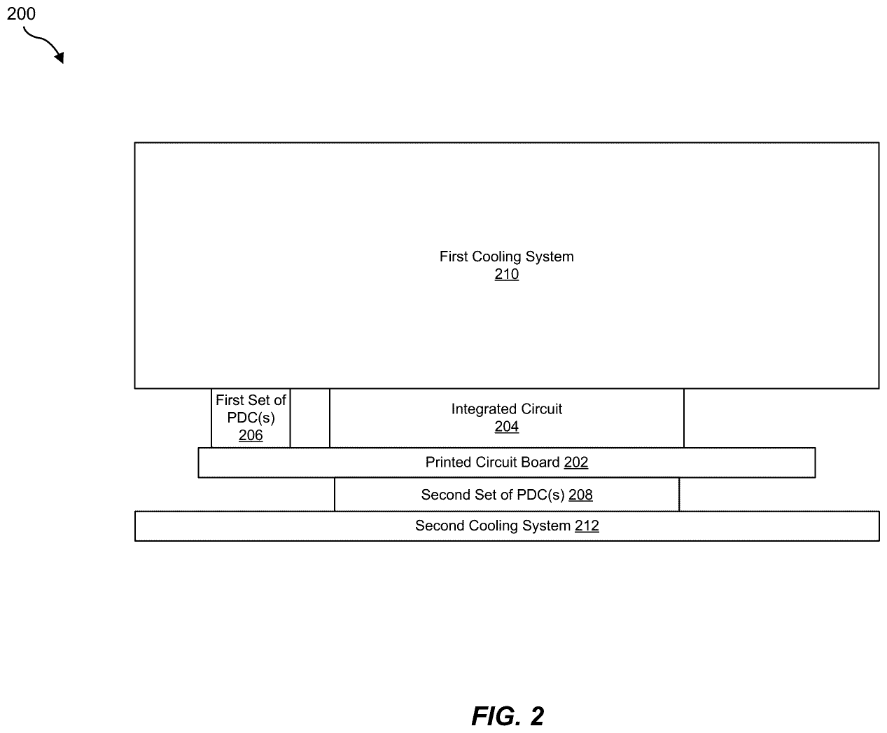

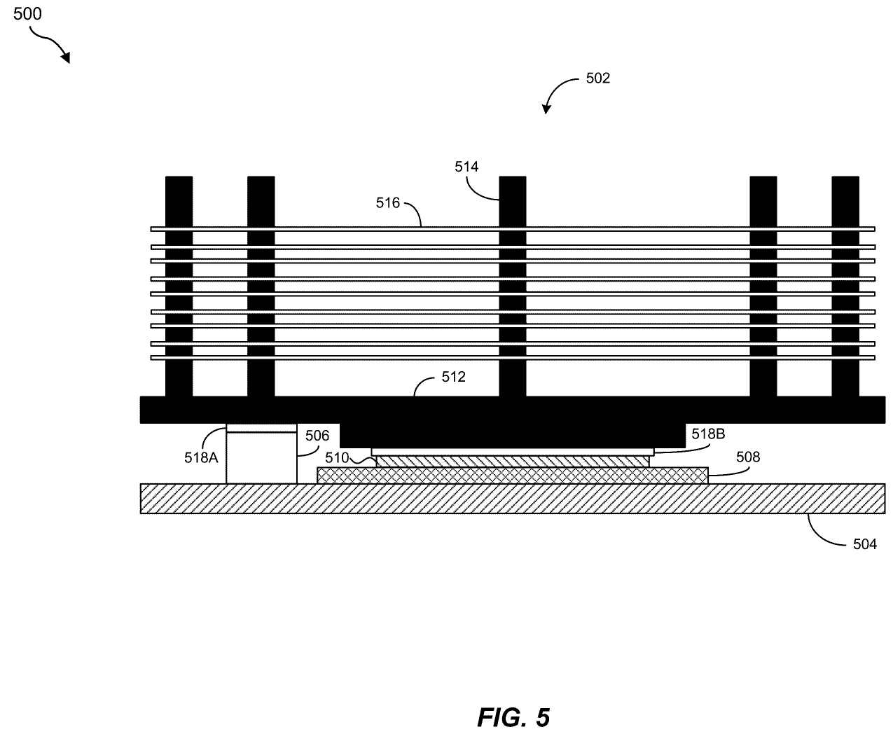

The following will provide, with reference to FIG. 1, detailed descriptions of example methods for cooling accelerators having back side power delivery components. In addition, detailed descriptions of example apparatuses for cooling accelerators having back side power delivery components will be provided in connection with FIGS. 2-4. Also, detailed descriptions of example apparatuses for cooling accelerators having back side power delivery components with a front side cooling system that includes an air cooled heat sink will be provided in connection with FIGS. 5-12.

In one example, an apparatus can include a printed circuit board having a first side that includes an integrated circuit and a first set of one or more power delivery components and a second side that is opposite the first side and that includes a second set of one or more power delivery components, a first cooling system positioned to cool the integrated circuit and the first set of one or more power delivery components, and a second cooling system positioned to cool the second set of one or more power delivery components.

Another example can be the previously described example apparatus, wherein the first cooling system and the second cooling system are directly coupled to one another.

Another example can be any of the previously described example apparatuses, wherein the second cooling system includes a heat transfer path between the first cooling system and the second cooling system.

Another example can be any of the previously described example apparatuses, wherein the heat transfer path includes a breakable heat transfer path configured to transfer thermal energy from the second cooling system to the first cooling system.

Another example can be any of the previously described example apparatuses, wherein the breakable heat transfer path is configured to transfer the thermal energy through a thermal interface material.

Another example can be any of the previously described example apparatuses, wherein the printed circuit board has one or more cutouts therein configured to accommodate passage therethrough of the heat transfer path.

Another example can be any of the previously described example apparatuses, wherein at least one of the first cooling system or the second cooling system has one or more fastener features configured to affect coupling of the first cooling system and the second cooling system.

Another example can be any of the previously described example apparatuses, wherein the first cooling system includes an air-cooled heat sink.

In one example, back side cooling system can include a cooling element configured to receive thermal energy from a first set of one or more power delivery components positioned on a back side of a printed circuit board having an integrated circuit and a second set of one or more power delivery components positioned on a front side of the printed circuit board, and a heat transfer path configured to directly couple the back side cooling system to a front side cooling system positioned to cool the integrated circuit and the second set of one or more power delivery components.

Another example can be the previously described example back side cooling system, wherein the heat transfer path includes a breakable heat transfer path configured to transfer thermal energy from the back side cooling system to the front side cooling system.

Another example can be any of the previously described example back side cooling systems, wherein the breakable heat transfer path is configured to transfer the thermal energy through a thermal interface material.

Another example can be any of the previously described example back side cooling systems, wherein the back side cooling system has one or more fastener features configured to affect coupling of the back side cooling system and the front side cooling system.

Another example can be any of the previously described example back side cooling systems, wherein the cooling element includes at least one copper plate, heat pipes, vapor chambers, three-dimensional vapor chambers, or combinations thereof, and the heat transfer path includes one or more copper pillars, copper blocks, heat pipes, vapor chambers, three-dimensional vapor chambers, or combinations thereof.

In one example, a method can include providing a printed circuit board having a first side that includes an integrated circuit and a first set of one or more power delivery components and a second side that is opposite the first side and that includes a second set of one or more power delivery components, positioning a first cooling system to cool the integrated circuit and the first set of one or more power delivery components, and positioning a second cooling system to cool the second set of one or more power delivery components.

Another example can be the previously described example method, further comprising directly coupling the first cooling system and the second cooling system to one another.

Another example can be any of the previously described example methods, wherein the second cooling system includes a heat transfer path between the first cooling system and the second cooling system.

Another example can be any of the previously described example methods, wherein the heat transfer path includes a breakable heat transfer path configured to transfer thermal energy from the second cooling system to the first cooling system.

Another example can be any of the previously described example methods, wherein the breakable heat transfer path is configured to transfer the thermal energy through a thermal interface material.

Another example can be any of the previously described example methods, wherein the printed circuit board has one or more cutouts therein configured to accommodate passage therethrough of the heat transfer path.

Another example can be any of the previously described example methods, wherein at least one of the first cooling system or the second cooling system has one or more fastener features configured to affect coupling of the first cooling system and the second cooling system.

FIG. 1 is a flow diagram of an example method 100 for cooling accelerators having back side power delivery components. As illustrated in FIG. 1, at step 102 one or more of the systems described herein can provide a printed circuit board. For example, step 102 can include providing a printed circuit board having a first side that includes an integrated circuit and a first set of one or more power delivery components and a second side that is opposite the first side and that includes a second set of one or more power delivery components.

The term “printed circuit board,” as used herein, can generally refer to a medium used in electrical and electronic engineering to connect electronic components to one another in a controlled manner. For example, and without limitation, a printed circuit board (PCB) can take the form of a laminated sandwich structure of conductive and insulating layers, with each of the conductive layers being designed with an artwork pattern of traces, planes, and other features (e.g., like wires on a flat surface) etched from one or more sheet layers of copper laminated onto and/or between sheet layers of a non-conductive substrate. Electrical components can be fixed to conductive pads on the outer layers in the shape designed to accept the component's terminals, generally by means of soldering, to both electrically connect and mechanically fasten them to it. Another manufacturing process can add vias, such as plated-through holes that allow interconnections between layers. PCBs can be single-sided (e.g., one copper layer), double-sided (e.g., two copper layers on both sides of one substrate layer), or multi-layer (e.g., outer and inner layers of copper, alternating with layers of substrate). Multi-layer PCBs allow for much higher component density because circuit traces on the inner layers would otherwise take up surface space between components.

The term “integrated circuit,” as used herein, can generally refer to a set of electronic circuits on one small flat piece (e.g., chip) of semiconductor material, usually silicon. For example, and without limitation, integrated circuits can correspond to central processing units (CPUs), field programmable gate arrays (FPGAs), and expansion cards (e.g., graphics accelerator cards).

The term “application specific integrated circuit,” as used herein, can generally refer to an integrated circuit (IC) chip customized for a particular use, rather than intended for general-purpose use. For example, and without limitation, ASICs can include Al accelerators, graphics accelerators, graphics processing units, etc. However, as noted above, some computing platforms allow using graphics cards for general-purpose computing. Thus, while an ASIC is not necessarily intended for use as a general purpose processor, an ASIC can nevertheless be capable of providing such functionality.

The term “power delivery components,” as used herein, can generally refer to an electricity regulation device. For example, and without limitation, power delivery component can refer to one or more voltage regulators. A voltage regulator is a system designed to automatically maintain a constant voltage. A voltage regulator can use a simple feed-forward design or include negative feedback. It can use an electromechanical mechanism or electronic components. Depending on the design, it can be used to regulate one or more alternating current (AC) or direct current (DC) voltages.

The systems described herein can perform step 102 in a variety of ways. In one example, the printed circuit board (PCB) can have one or more cutouts therein configured to accommodate passage therethrough of a heat transfer path. In some of these implementations, the PCB board can have a substrate and a first set of one or more power delivery components coupled thereto on a front side of the PCB. In some of these implementations, the substrate can have a die that includes an integrated circuit (e.g., application specific integrated circuit (ASIC) accelerator, etc.) couple thereto. In some of these implementations, the PCB can have one or more layers of thermal interface material (TIM) positioned to overlay the die and/or the first set of one or more power delivery components.

At step 104 one or more of the systems described herein can position a first cooling system. For example, step 104 can include positioning a first cooling system to cool the integrated circuit and the first set of one or more power delivery components.

The term “cooling system,” as used herein, can generally refer to passive or active systems that are designed to regulate and dissipate the heat generated by a computer to maintain optimal performance and protect the computer from damage that will occur from overheating. For example, and without limitation, example cooling systems can include a heat sink that is air-cooled and/or liquid-cooled. In this context, an air-cooled heat sink can include a heat transfer path (e.g., copper pillars, copper blocks, heat pipes, vapor chambers, three-dimensional vapor chambers, or combinations thereof) and various cooling path configurations (e.g., cooling channels, pin fins, serpentine channels, etc.). Similarly, a liquid-cooled heat sink can include one or more cold plates and/or one or more heat pipes, and the cold plate can have various internal cooling fluid path configurations (e.g., cooling channels, pin fins, serpentine channels, etc.). Cooling systems can also include thermal interface material that goes into joints to fill air gaps between solid surfaces during assembly. Thermal interface material can correspond to, be combined with, and/or include one or more heat spreaders that have high thermal conductivity and can be used as a bridge between a heat source and a heat exchanger.

The systems described herein can perform step 104 in a variety of ways. In one example, the first cooling system provided in step 104 can include an air-cooled heat sink. Alternatively or additionally, the first cooling system can have one or more fastener features configured to affect coupling of the first cooling system and a second cooling system.

The term “fastener features,” as used herein, can generally refer to any device or portion thereof that is used to mechanically join (e.g., fasten and/or affix) two or more objects together. For example, and without limitation, a fastener can correspond to one or more through holes, threaded through holes, screws, bolts, pins, clasps, flanges, hinges, battens, snaps, buckles, buttons, ties, cams, clamps, shackles, clecos, clips, clutches, frogs, grommets, hooks, eyes, loops, latches, nails, rivets, pegs, nuts, rings, bands, anchors, staples, stitches, straps, tags, and/or zippers. In general, fasteners can be used to create non-permanent joints; that is, joints that can be removed or dismantled without damaging the joining components.

At step 106 one or more of the systems described herein can position a second cooling system. For example, step 106 can include positioning a second cooling system to cool the second set of one or more power delivery components.

The systems described herein can perform step 106 in a variety of ways. In one example, step 106 can include directly coupling (permanently (e.g., with an adhesive and/or weld) or non-permanently (e.g., with a fastener)) the first cooling system and the second cooling system to one another. In some of these implementations, the second cooling system can include a heat transfer path (e.g., copper pillars, copper blocks, heat pipes, vapor chambers, three-dimensional vapor chambers, or combinations thereof) between the first cooling system and the second cooling system. In some of these implementations, the heat transfer path can be a breakable heat transfer path configured to transfer thermal energy from the second cooling system (e.g., from a cooling element (e.g., copper plate, heat pipes, vapor chambers, three-dimensional vapor chambers, or combinations thereof)) to the first cooling system. In some of these implementations, the breakable heat transfer path can be configured to transfer the thermal energy through a thermal interface material. In an additional or alternative example, the first cooling system and/or the second cooling system can have one or more fastener features configured to affect coupling of the first cooling system and the second cooling system. Additionally or alternatively, the first cooling system and/or the second cooling system can have one or more fastener features configured to affect coupling of the first cooling system and the second cooling system. Alternatively or additionally, a mechanical stiffener can have one or more features that hold the first and second cooling systems in positions to affect coupling of the first cooling system and the second cooling system.

FIG. 2 shows an example apparatus 200 implementing systems and methods for cooling accelerators having back side power delivery components. Apparatus 200 can include a PCB 202 having a first side that includes an integrated circuit 204 (e.g., ASIC, accelerator, etc.) and a first set of one or more power delivery components 206 (PDCs). Apparatus 200 can also have a second side that is opposite the first side and that includes a second set of one or more PDCs 208. Apparatus 200 can additionally have a first (e.g., front side) cooling system 210 (e.g., air-cooled and/or liquid cooled) positioned to cool the integrated circuit 204 and the first set of one or more PDCs 206. Apparatus 200 can further have a second cooling system 212 (e.g., air-cooled and/or liquid cooled) positioned to cool the second set of one or more PDCs 208.

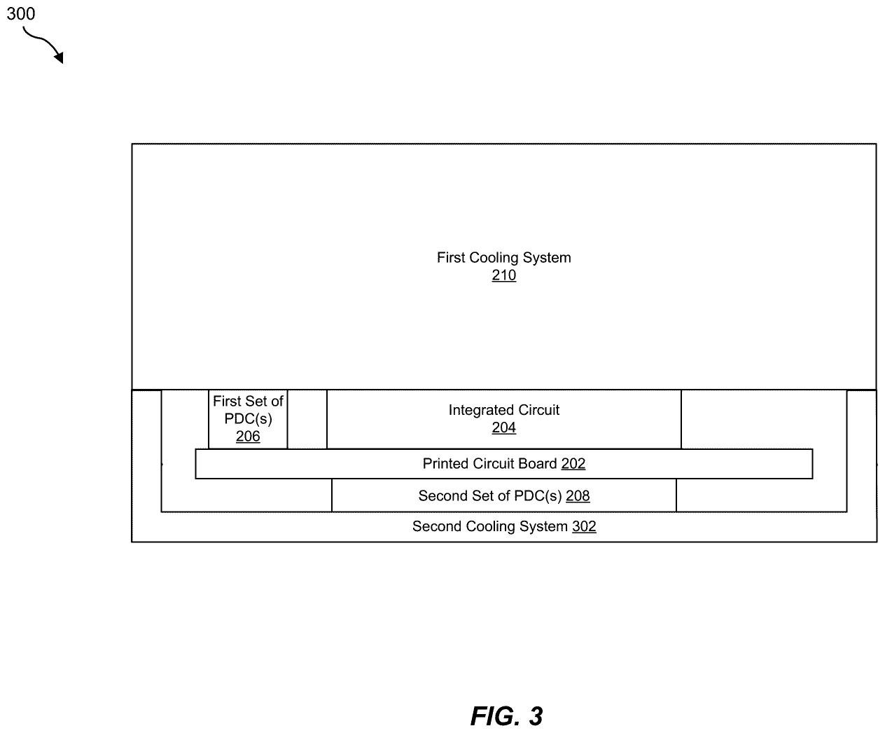

FIG. 3 shows an example apparatus 300 implementing systems and methods for cooling accelerators having PCB 202, integrated circuit 204, first set of one or more PDCs 206, second set of one or more PDCs 208, and first cooling system 210 as described above with reference to FIG. 2. As shown in FIG. 3, a second cooling system 302 of apparatus 300 can directly couple to first cooling system 210. In some implementations, second cooling system 302 can include a heat transfer path (e.g., copper pillars, copper blocks, heat pipes, vapor chambers, three-dimensional vapor chambers, or combinations thereof) between the first cooling system 210 and at least part (e.g., a cooling element (e.g., copper plate, heat pipes, vapor chambers, three-dimensional vapor chambers, or combinations thereof) of the second cooling system 302. In some of these implementations, the heat transfer path can correspond to a breakable heat transfer path configured to transfer thermal energy from the second cooling system 302 to the first cooling system 210. In some of these implementations, the breakable heat transfer path can be configured to transfer the thermal energy through a thermal interface material (e.g., positioned in a gap between the heat transfer path and the first cooling system). In some implementations, the first cooling system 210 and/or the second cooling system 302 can have one or more fastener features configured to affect coupling (e.g., direct coupling) of the first cooling system 210 and the second cooling system 302.

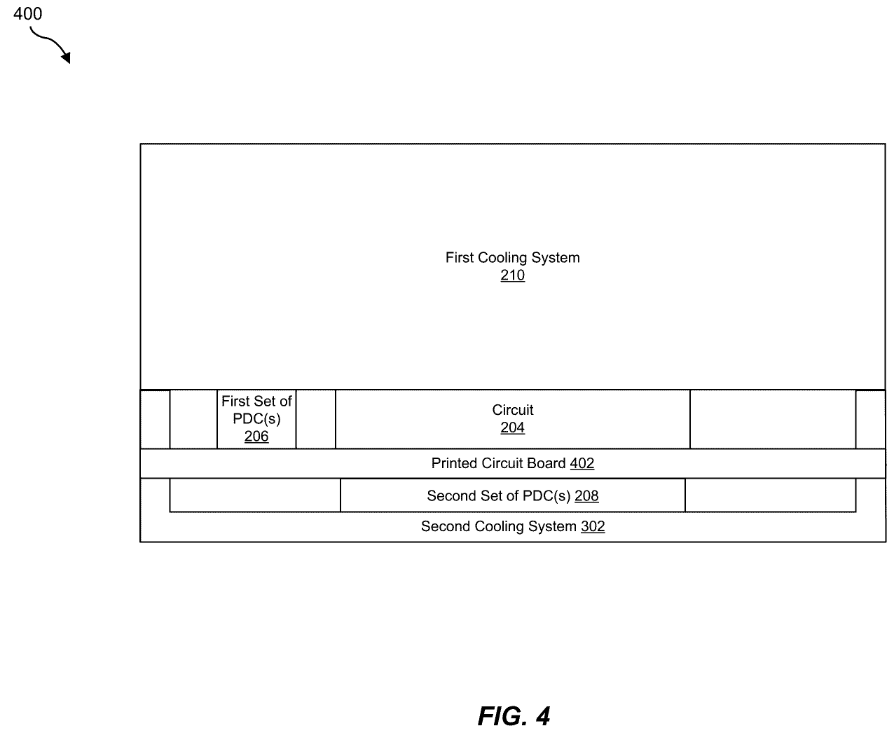

FIG. 4 shows an example apparatus 400 implementing systems and methods for cooling accelerators having integrated circuit 204, first set of one or more PDCs 206, second set of one or more PDCs 208, first cooling system 210, and second cooling system 302 as described above with reference to FIGS. 2 and 3. As shown in FIG. 4, a PCB 402 of apparatus 400 can have one or more cutouts therein configured to accommodate passage therethrough of a heat transfer path (e.g., copper pillars, copper blocks, heat pipes, vapor chambers, three-dimensional vapor chambers, or combinations thereof) of second cooling system 302. For example, these cutouts can be provisioned in PCB 402 to allow PCB 402 to adhere to the x and y dimensions for a PCB board specified by industry standards (e.g., OAM 2.0).

FIG. 5 shows an example apparatus 500 having a front side cooling system that includes an air-cooled heat sink 502. For example, apparatus 500 can have a PCB 504, front side PDC(s) 506, a substrate 508, and an integrated circuit 510 (e.g., accelerator) arranged as shown. Air-cooled heat sink 502 can have a cooling element 512 (e.g., a copper plate, heat pipes, vapor chambers, three-dimensional vapor chambers, or combinations thereof), a heat transfer path 514 (e.g., copper plate, heat pipes, vapor chambers, three-dimensional vapor chambers, or combinations thereof), and one or more heat spreaders, such as a plurality of pin fins 516, arranged as shown. Air-cooled heat sink 502 can be positioned to cool front side PDC(s) 506 and integrated circuit 510 by placing the cooling element atop the front side PDC(s) 506 and the integrated circuit with one or more layers of thermal interface material 518A and 518B filling a gap between the cooling element and the front side PDC(s) 506 and integrated circuit 510.

Apparatus 500 can encounter challenges in meeting power delivery requirements and thermal requirements on accelerator cards due to the limited availability of PCB real estate for voltage regulators. The available PCB real estate for voltage regulators, primarily on the front side of the card, can set the upper limit of the amount of power that can be delivered to the accelerator (e.g., no more than 750 Watts), thus limiting performance of the accelerator.

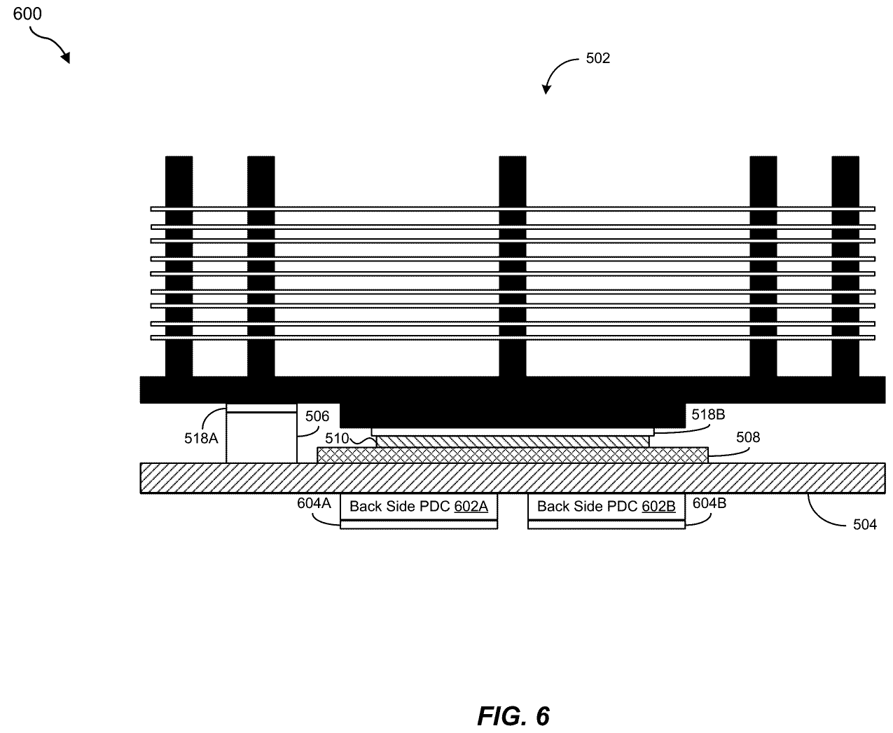

FIG. 6 shows an example apparatus 600 having air-cooled heat sink 502, PCB 504, front side PDC(s) 506, substrate 508, integrated circuit 510, and thermal interface material 518A and 518B as described above with reference to FIG. 5. Apparatus 600 can also include backside PDC(s) 602A and 602B and one or more layers of thermal interface material 604A and 604B arranged as shown. Placing highly integrated voltage regulators on the backside of the accelerator card, underneath the processor, enables increase of total power delivered to accelerator and, thus, increase in performance of the accelerator.

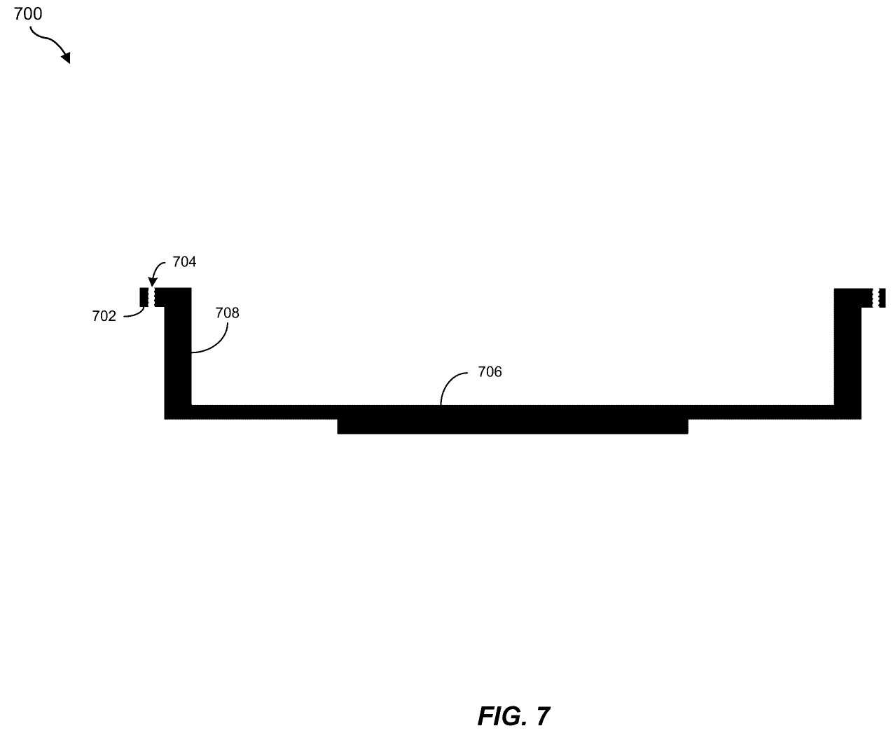

FIG. 7 shows an example back side cooling system 700 having one or more fastener features, such as one or more flanges 702 including one or more threaded through holes 704. Back side cooling system 700 can include a cooling element 706 (e.g., copper plate, heat pipes, vapor chambers, three-dimensional vapor chambers, or combinations thereof) and a heat transfer path 708 (e.g., copper pillars, copper blocks, heat pipes, vapor chambers, three-dimensional vapor chambers, or combinations thereof) configured as shown. Cooling element 706 can be configured to cool back side PDC(s) 602A and 602B of apparatus 600 of FIG. 6, and heat transfer path 708 can be configured to directly couple back side cooling system 700 to air-cooled heat sink 502 of apparatus 600 of FIG. 6. The fastener features, such as one or more flanges 702 including one or more threaded through holes 704, can configure heat transfer path 708 as a breakable heat transfer path configured to transfer thermal energy from cooling element 706 to air-cooled heat sink 502 of apparatus 600 of FIG. 6.

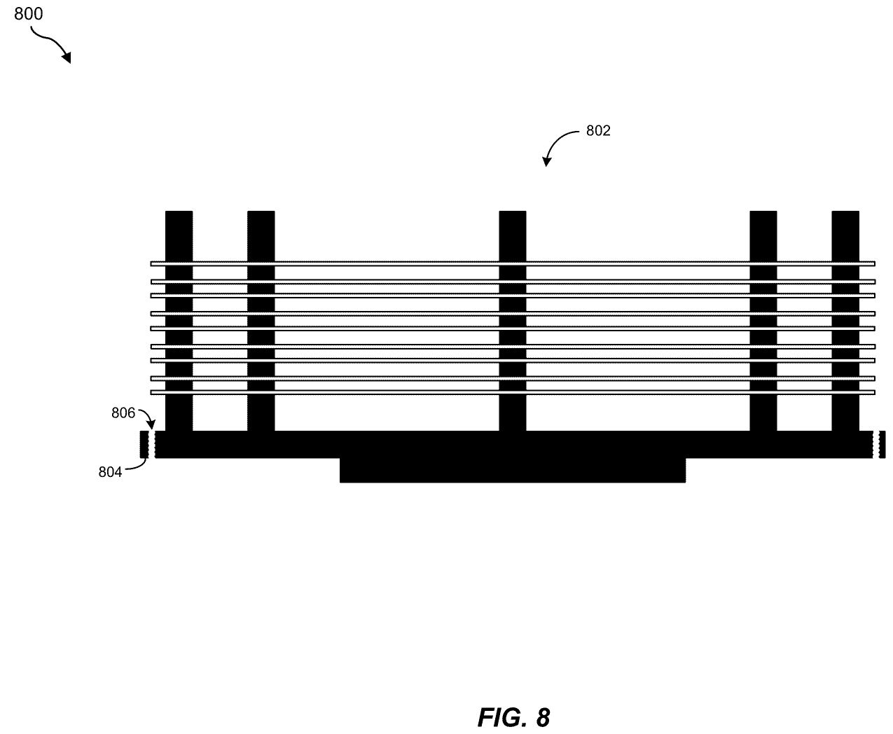

FIG. 8 shows an example front side cooling system 800 that includes an air-cooled heat sink 802 and one or more fastener features, such as one or more flanges 804 and one or more threaded through holes 806. Air cooled heat sink 802 can have features as described above with reference to air-cooled heat sink 502 of FIGS. 5 and 6. The one or more fastener features can be provided to air-cooled heat sink 802 by forming one or more threaded through holes 806 in flanges 804. The fastener features, such as one or more flanges 804 including one or more threaded through holes 806, can configure air-cooled heat sink 802 to couple directly to breakable heat transfer path 708 of back side cooling system 700 of FIG. 7 and receive thermal energy transferred from cooling element 706 to air-cooled heat sink 802.

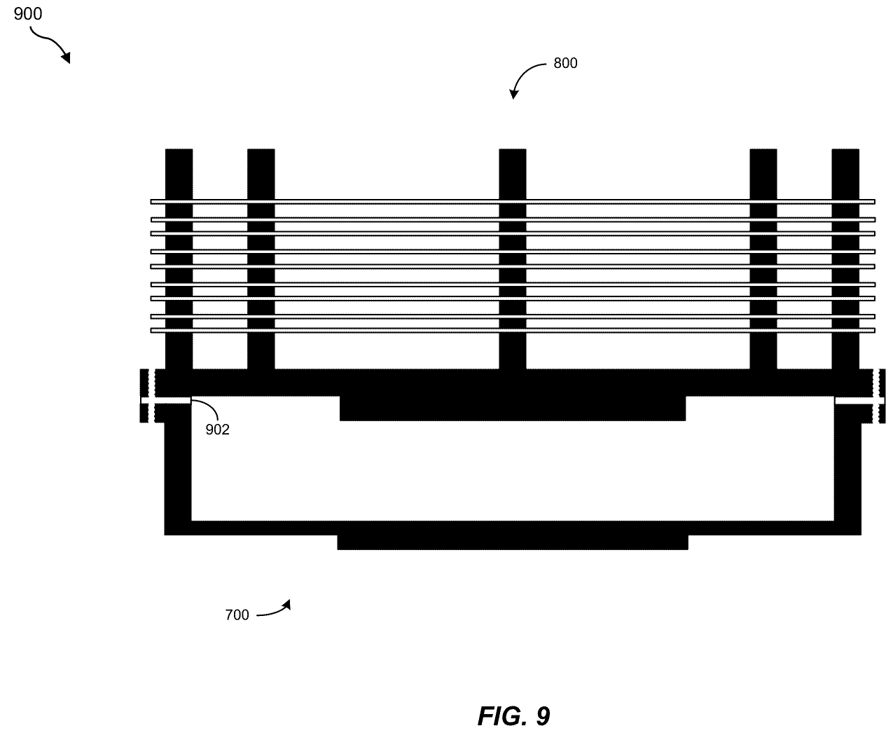

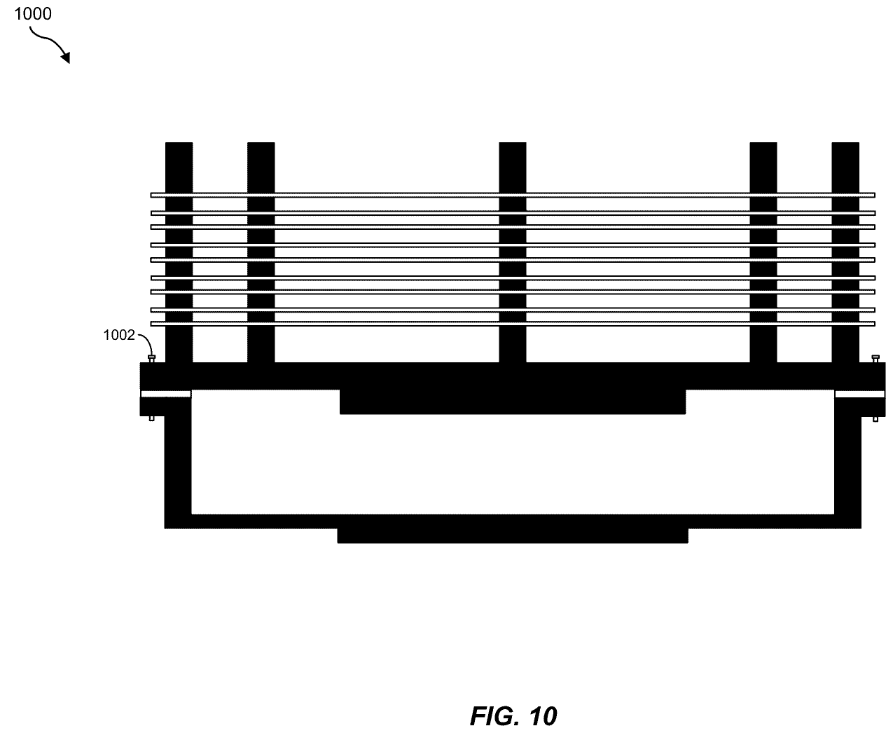

FIG. 9 shows an example cooling system 900 including front side cooling system 800 of FIG. 8 directly coupled to back side cooling system 700 of FIG. 7 with thermal energy being transferred therebetween through one or more layers of thermal interface material 902 arranged as shown. As shown in FIG. 10 at 1000, one or more fasteners, such as one or more threaded machine screws 1002 inserted through threaded through holes formed in flanges of front side cooling system 800 of FIG. 8 and back side cooling system 700 of FIG. 7, can affect the direct coupling thereof and achieve the breakable heat transfer path. The breakable heat transfer path arranged in this manner can realize easy assembly and disassembly while using current standard operating procedures (e.g., avoiding a requirement for complex tools).

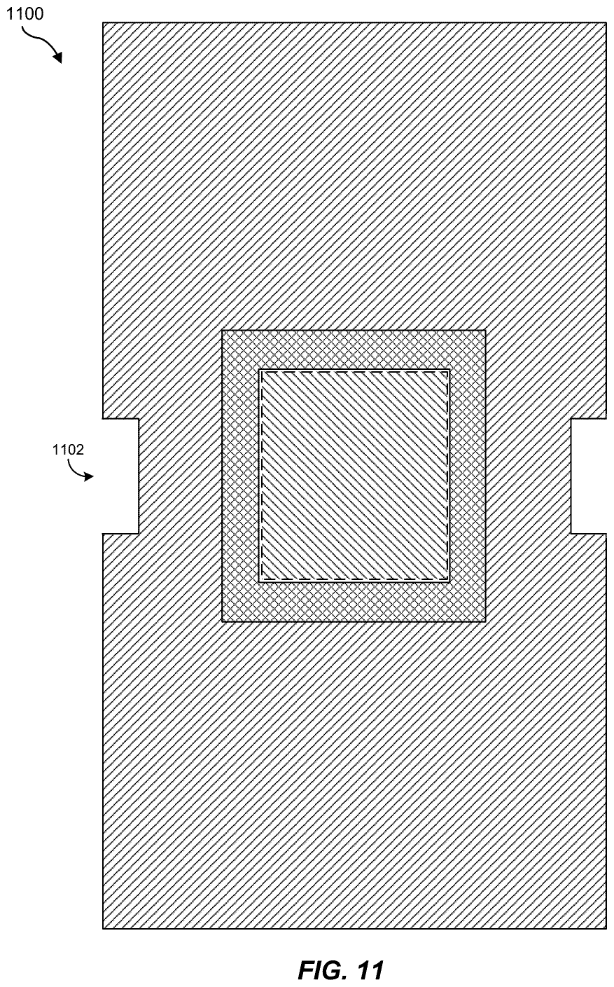

FIG. 11 shows a printed circuit board 1100 having one or more cutouts 1102 therein configured to accommodate passage therethrough of a heat transfer path. For example, the one or more cutouts 1102 can be provisioned at an edge of the PCB 1100, away from a substrate 508, integrated circuit 510, and thermal interface material 518B on a front side of PCB 1100. The one or more cutouts 1102 can be provisioned away from back side PDCs on a back side of PCB 1100. One or more cutouts 1102 can permit direct coupling of the front side and back side cooling systems while enabling PCB 1100 to have sufficient PCB real estate and still adhere to x and y dimensions of PCBs specified in industry standards.

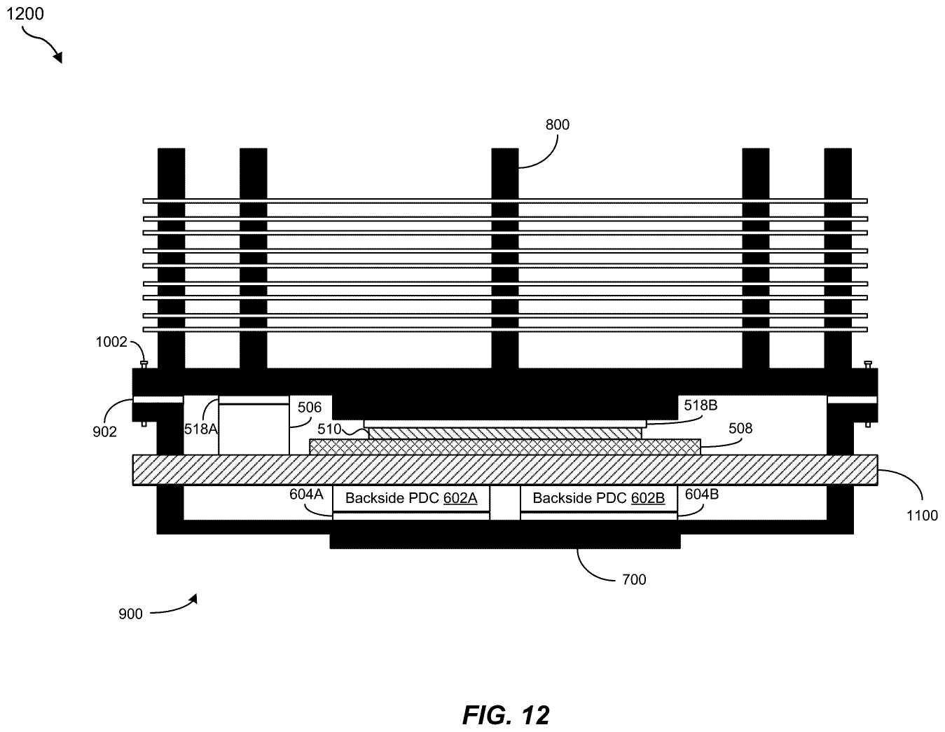

FIG. 12 shows an example apparatus 1200 that includes cooling system 900 of FIG. 9 positioned to cool integrated circuit 510, front side PDC(s) 506, and backside PDC(s) 602A and 602B of FIG. 6 arranged as shown on respective sides of PCB 1100 of FIG. 11. Integrated circuit 510 can be arranged atop a substrate 508 on a front side of PCB 1100 as shown. Cutouts in PCB 1100 can allow passage therethrough of a heat transfer path of back side cooling system 700 of FIG. 7 to allow direct coupling thereof to front side cooling system 800 of FIG. 8. One or more layers of thermal interface material 518A, 518B, 604A, and 604B, of FIGS. 6 and 902 of FIG. 9 can fill gaps as shown. Fastener features of back side cooling system 700 of FIG. 7 and front side cooling system 800 of FIG. 8 can enable direct coupling thereof using one or more fasteners (e.g., one or more threaded machine screws 1002 of FIG. 10) and achieve the breakable heat transfer path. The breakable heat transfer path arranged in this manner can realize easy assembly and disassembly while using current standard operating procedures (e.g., avoiding a requirement for complex tools). With this arrangement, apparatus 1200 can achieve increased power (e.g., greater than 800 Watts up to 1200 Watts) and performance with air-cooling while avoiding a need for any new data center infrastructure with air flow rates being similar to existing platform boundary conditions.

As set forth above, the disclosed systems and methods can cool accelerators having back side power delivery components. For example, by positioning a first cooling system (e.g., including an air cooled heat sink) to cool an integrated circuit and a first set of one or more power delivery components on a front side of a printed circuit board, and by positioning a second cooling system (e.g., including a cooling element (e.g., copper plate, heat pipes, vapor chambers, three-dimensional vapor chambers, or combinations thereof)) to cool a second set of one or more power delivery components on a back side of the printed circuit board, the disclosed systems and methods can cool an accelerator having back side power delivery components. In some implementations, the disclosed systems and methods can include direct coupling of the first cooling system and the second cooling system to one another. In some of these implementations, the second cooling system can include a heat transfer path (e.g., copper pillars, copper blocks, heat pipes, vapor chambers, three-dimensional vapor chambers, or combinations thereof) between the first cooling system and the second cooling system. In some of these implementations, the heat transfer path can be a breakable heat transfer path that can be configured to transfer the thermal energy through a thermal interface material. Alternatively or additionally, some of these implementations can include a printed circuit board having one or more cutouts therein configured to accommodate passage therethrough of the heat transfer path.

As also set forth above, the disclosed systems and methods can yield numerous benefits. For example, some implementations of the disclosed systems and methods can enable higher power (e.g., greater than 800 Watts) and performance with air-cooling. Additionally, some implementations of the disclosed systems and methods can avoid a need for any new data center infrastructure with air flow rates being similar to existing platform boundary conditions. Also, some implementations of the disclosed systems and methods can incorporate the back side cooling system within a bottom stiffener, thus improving structural rigidity. Further, some implementations of the disclosed systems and methods can realize easy assembly and disassembly by using a breakable heat transfer path while using current standard operating procedures (e.g., avoiding a requirement for complex tools). Further, some implementations of the disclosed systems and methods can exhibit reduced printed circuit board (PCB) copper planes and numbers of layers, thus achieving a reduced PCB cost. Further, some implementations of the disclosed systems and methods can experience reduced power path resistance between a voltage regulator and a processor, thus achieving reduced PCB copper losses, increased conversion efficiency, increased useful throughput power, and reduced power delivery network (PDN) impedance from a voltage regulator to a processor for reduced PDN noise. Finally, some implementations of the disclosed systems and methods can provide a low profile cooling system that allows a combination of the cooling system and the backside PDCs to fit within open compute project (OCP) accelerator module (OAM) form factors (e.g., eight millimeters of clearance on the back side of the PCB).

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An apparatus, comprising:
a printed circuit board having a first side that includes an integrated circuit and a first set of one or more power delivery components and a second side that is opposite the first side and that includes a second set of one or more power delivery components;
a first cooling system positioned to cool the integrated circuit and the first set of one or more power delivery components; and
a second cooling system positioned to cool the second set of one or more power delivery components.

2. The apparatus of claim 1, wherein the first cooling system and the second cooling system are directly coupled to one another.

3. The apparatus of claim 2, wherein the second cooling system includes a heat transfer path between the first cooling system and the second cooling system.

4. The apparatus of claim 3, wherein the heat transfer path comprises a breakable heat transfer path configured to transfer thermal energy from the second cooling system to the first cooling system.

5. The apparatus of claim 4, wherein the breakable heat transfer path is configured to transfer the thermal energy through a thermal interface material.

6. The apparatus of claim 3, wherein the printed circuit board has one or more cutouts therein configured to accommodate passage therethrough of the heat transfer path.

7. The apparatus of claim 2, wherein at least one of the first cooling system or the second cooling system has one or more fastener features configured to affect coupling of the first cooling system and the second cooling system.

8. The apparatus of claim 1, wherein the first cooling system includes an air-cooled heat sink.

9. A back side cooling system comprising:
a cooling element configured to receive thermal energy from a first set of one or more power delivery components positioned on a back side of a printed circuit board having an integrated circuit and a second set of one or more power delivery components positioned on a front side of the printed circuit board; and
a heat transfer path configured to directly couple the back side cooling system to a front side cooling system positioned to cool the integrated circuit and the second set of one or more power delivery components.

10. The back side cooling system of claim 9, wherein the heat transfer path comprises a breakable heat transfer path configured to transfer thermal energy from the back side cooling system to the front side cooling system.

11. The back side cooling system of claim 10, wherein the breakable heat transfer path is configured to transfer the thermal energy through a thermal interface material.

12. The back side cooling system of claim 9, wherein the back side cooling system has one or more fastener features configured to affect coupling of the back side cooling system and the front side cooling system.

13. The back side cooling system of claim 9, wherein the cooling element includes at least one copper plate, heat pipes, vapor chambers, three-dimensional vapor chambers, or combinations thereof, and the heat transfer path includes one or more copper pillars, copper blocks, heat pipes, vapor chambers, three-dimensional vapor chambers, or combinations thereof.

14. A method comprising:
providing a printed circuit board having a first side that includes an integrated circuit and a first set of one or more power delivery components and a second side that is opposite the first side and that includes a second set of one or more power delivery components;
positioning a first cooling system to cool the integrated circuit and the first set of one or more power delivery components; and
positioning a second cooling system to cool the second set of one or more power delivery components.

15. The method of claim 14, further comprising directly coupling the first cooling system and the second cooling system to one another.

16. The method of claim 15, wherein the second cooling system includes a heat transfer path between the first cooling system and the second cooling system.

17. The method of claim 16, wherein the heat transfer path comprises a breakable heat transfer path configured to transfer thermal energy from the second cooling system to the first cooling system.

18. The method of claim 17, wherein the breakable heat transfer path is configured to transfer the thermal energy through a thermal interface material.

19. The method of claim 16, wherein the printed circuit board has one or more cutouts therein configured to accommodate passage therethrough of the heat transfer path.

20 The method of claim 14, wherein at least one of the first cooling system or the second cooling system has one or more fastener features configured to affect coupling of the first cooling system and the second cooling system.
